(19) United States
(12) Patent Application Publication
(10) Pub. No.: US 2015/0014729 A1
(43) Pub. Date: Jan. 15, 2015

(54) RESIN COMPOSITION FOR REFLECTING LIGHT, SUBSTRATE FOR MOUNTING OPTICAL SEMICONDUCTOR ELEMENT, AND OPTICAL SEMICONDUCTOR DEVICE

(71) Applicant: SUMITOMO BAKELITE COMPANY LIMITED, Tokyo (JP)

(72) Inventors: Masaharu Ito, Tokyo (JP); Keiichi Tsukurimichi, Tokyo (JP)

(73) Assignee: SUMITOMO BAKELITE COMPANY LIMITED, Tokyo (JP)

(21) Appl. No.: 14/376,032

(22) PCT Filed: Mar. 14, 2013
(86) PCT No.: PCT/JP2013/001693

§ 371 Date: Jul. 31, 2014

(30) Foreign Application Priority Data
Mar. 27, 2012 (JP) 2012-072566
May 16, 2012 (JP) 2012-112746
Jul. 2, 2012 (JP) 2012-148620

(51) Int. Cl. H01L 33/60; C08L 63/00

(52) U.S. Cl. CPC H01L 33/60; C08L 63/00; C08L 2203/20; C08L 2205/025
USPC 257/98; 523/400; 523/427

(57) ABSTRACT

A resin composition for reflecting light of the present invention includes an epoxy resin B having a unit structure X of alicyclic acid anhydride and a unit structure Y of hydrogenated bisphenol, and a colorant. The epoxy resin B preferably further has a unit structure Z of bisphenol-type epoxy. In addition, the resin composition for reflecting light of the present invention preferably further includes an epoxy resin A having a structure represented by the following formula (1). Then, when a content of the epoxy resin A is M [% by mass], and a content of the epoxy resin B is N [% by mass], it is preferable to satisfy a relationship of 0.1≦M/N≦10.

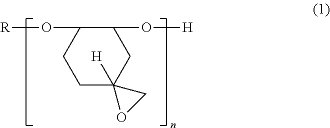

(In the formula (1), R represents a monovalent organic group having 2 to 10 carbon atoms, and n represents an integer of 3 to 50.)

### TECHNICAL FIELD

The present invention relates to a resin composition for reflecting light, a substrate for mounting optical semiconductor element, and an optical semiconductor device.

### BACKGROUND ART

In the related art, in the optical semiconductor device provided with a light emitting element such as a Light Emitting Diode (LED), usually, to effectively use light emitted from the light emitting element, a light-reflecting member (for example, a white film, a white coating film, a silver color film, and a silver color coating film) is disposed near the light emitting element, and improvement of reflectivity is achieved.

Such a light-reflecting member is generally constituted with a resin composition (resin composition for reflecting light) including a resin, a curing agent, a colorant, and the like (for example, see Patent Document 1).

However, the resin compositions for reflecting light used in the related art had low moldability, and was difficult to be molded into a desired shape. In addition, the resin compositions for reflecting light in the related art had low heat resistance, and had a problem in that yellowing occurs by heat at the time of molding, heat at the time of solder joint, heat of light emitting elements, or the like, and thus reflectance is decreased. In addition, there was also a problem in that peeling off or cracking occur in a light-reflecting member by heat.

### RELATED DOCUMENT

### Patent Document

[Patent Document 1] Japanese Unexamined Patent Publication No. 2008-144127

### DISCLOSURE OF THE INVENTION

An object of the present invention is to provide a resin composition for reflecting light having excellent heat resistance, and a substrate for mounting optical semiconductor element and an optical semiconductor device having excellent reliability.

Such an object is achieved using the invention described in the following (1) to (15).

(1) A resin composition for reflecting light including an epoxy resin B having a unit structure X of alicyclic acid anhydride and a unit structure Y of hydrogenated bisphenol, and a colorant.

(2) The resin composition for reflecting light described in (1), in which the epoxy resin B further has a unit structure Z of bisphenol-type epoxy.

(3) The resin composition for reflecting light described in (1) or (2), further including an epoxy resin A having a structure represented by the following formula (1).

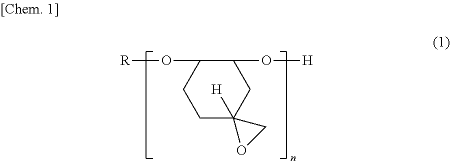

(In the formula (1), R represents a monovalent organic group having 2 to 10 carbon atoms, and n represents an integer of 3 to 50.)

(4) The resin composition for reflecting light described in (3) satisfying a relationship of 0.1≦M/N≦10 when a content of the epoxy resin A is M [% by mass], and a content of the epoxy resin B is N [% by mass].

(5) The resin composition for reflecting light described in (3) or (4), in which the content of the epoxy resin A is 1% by mass to 15% by mass.

(6) The resin composition for reflecting light described in any one of (1) to (5), in which the content of the epoxy resin B is 1% by mass to 15% by mass.

(7) The resin composition for reflecting light described in any one of (1) to (6), further including an epoxy resin C having an isocyanuric ring.

(8) The resin composition for reflecting light described in (7), in which a content of the epoxy resin C is 1% by mass to 15% by mass.

(9) The resin composition for reflecting light described in any one of (1) to (8), further including a curing agent.

(10) The resin composition for reflecting light described in any one of (1) to (9), in which a concentration of iron ions is less than or equal to 15 ppm.

(11) The resin composition for reflecting light described in any one of (1) to (10), including an inorganic filler, in which a content of the inorganic filler is greater than or equal to 30% by mass.

(12) The resin composition for reflecting light described in any one of (1) to (11), in which the colorant is titanium oxide.

(13) The resin composition for reflecting light described in any one of (1) to (12), in which a content of the colorant is less than or equal to 50% by mass.

(14) A substrate for mounting optical semiconductor element provided with a reflecting member constituted with a resin composition for reflecting light described in any one of (1) to (13).

(15) An optical semiconductor device provided with a reflecting member constituted with a resin composition for reflecting light described in any one of (1) to (13) and a light emitting element.

According to the present invention, it is possible to provide a resin composition for reflecting light capable of preventing deterioration of characteristics due to yellowing or the like by the heat at the time of molding, the heat of light emitting elements, or the like.

In addition, according to the present invention, it is possible to provide a substrate for mounting optical semiconductor element and an optical semiconductor device having excellent reliability.

### BRIEF DESCRIPTION OF THE DRAWINGS

The above-mentioned object, the other objects, the features, and the advantage are further described in detail with reference to preferred embodiments to be described later and the following accompanying drawings.

FIG. 1 shows a longitudinal cross-sectional view showing a first embodiment of a substrate for mounting optical semiconductor element.

FIG. 2 shows a longitudinal cross-sectional view showing the first embodiment of an optical semiconductor device.

FIG. 3 shows a longitudinal cross-sectional view showing a second embodiment of the optical semiconductor device.

### DESCRIPTION OF EMBODIMENTS

Hereinafter, the resin composition for reflecting light, the substrate for mounting optical semiconductor element, and the optical semiconductor device of the present invention will be described in detail on the basis of preferred embodiments shown in the accompanying drawings.

<<A First Embodiment of a Substrate for Mounting Optical Semiconductor Element and an Optical Semiconductor Device>>

First, before describing the resin composition for reflecting light of the present invention, a first embodiment of the substrate for mounting optical semiconductor element and the optical semiconductor device will be described.

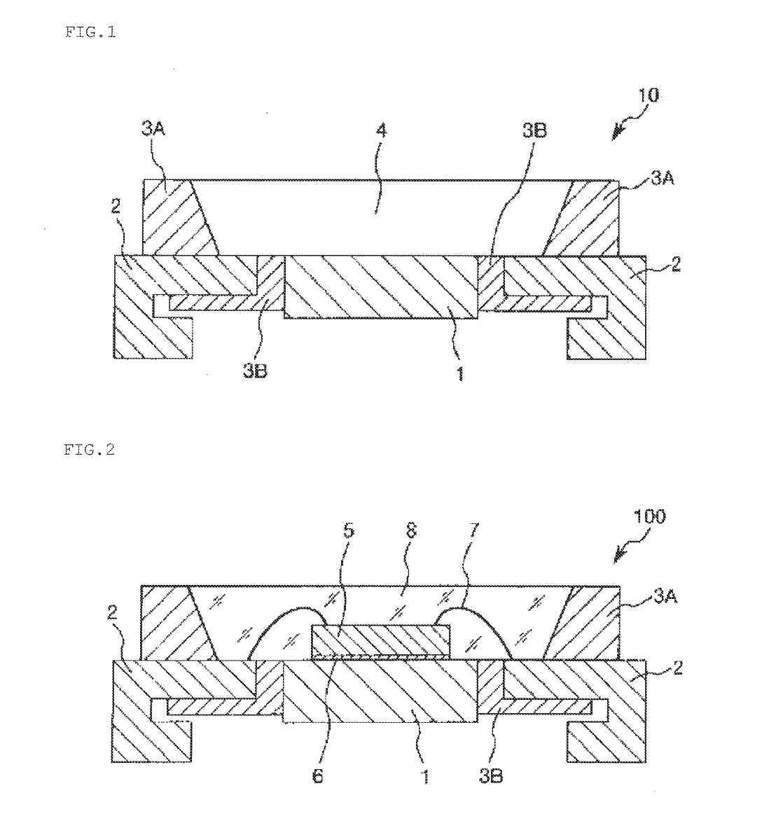

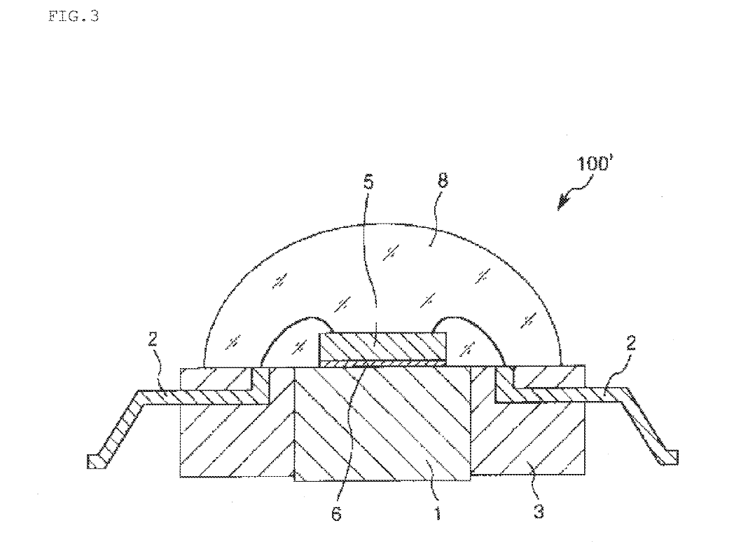

FIG. 1 is a longitudinal cross-sectional view showing the first embodiment of the substrate for mounting optical semiconductor element and FIG. 2 is a longitudinal cross-sectional view showing the first embodiment of the optical semiconductor device.

[Substrate for Mounting Optical Semiconductor Element]

As shown in FIG. 1, a substrate for mounting optical semiconductor element 10 according to the embodiment has a mounting portion 1 over which an optical semiconductor element 5 is mounted, a wire pattern 2 which is disposed adjacent to the mounting portion 1, a reflecting member 3A which is formed so as to surround the mounting portion 1, and a reflecting member 3B which is installed between the mounting portion 1 and the wire pattern 2.

The mounting portion 1 is a portion over which the optical semiconductor element 5 described below is mounted, and positioned on substantially the center of the substrate for mounting optical semiconductor element 10.

The mounting portion 1 is constituted with a material having conductivity, and constituted so as to be electrically connected to the optical semiconductor element 5.

The wire pattern 2 is disposed around the mounting portion 1, and constituted with a material having conductivity in the same manner as the mounting portion 1.

The wire pattern 2 is constituted so as to be electrically connected to the optical semiconductor element 5 by a bonding wire 7 described below.

Reflecting members 3A and 3B are constituted with the resin composition for reflecting light of the present invention described below.

The reflecting members 3A and 3B are provided with a function of reflecting light which is emitted by the optical semiconductor element 5.

The reflecting member 3A is formed so as to surround the mounting portion 1 (the optical semiconductor element 5). In addition, a surface of the reflecting member 3A on the mounting portion 1 side is inclined toward the outside. By such a reflecting member 3A, a concave portion 4 of which a bottom portion is the mounting portion 1 is formed.

In addition, the reflecting member 3B is formed so as to be buried between the mounting portion 1 and the wire pattern 2, and is formed integrally with the reflecting member 3A.

[Optical Semiconductor Device]

An optical semiconductor device 100, as shown in FIG. 2, has the substrate for mounting optical semiconductor element 10 described above and the optical semiconductor element 5 which is mounted over the mounting portion 1 of the substrate for mounting optical semiconductor element 10.

The optical semiconductor element 5 is mounted over the mounting portion 1 of the substrate for mounting optical semiconductor element 10 by a die attach material 6 (die attach paste, die attach film, or the like).

In addition, the optical semiconductor element 5 is electrically connected to the wire pattern 2 by the bonding wire 7.

In addition, the optical semiconductor element 5 and the bonding wire 7 are encapsulated with a transparent encapsulating material 8 as shown in FIG. 2. Moreover, a phosphor may be added in the transparent encapsulating material.

Examples of the optical semiconductor element 5 include light emitting elements such as a Light Emitting Diode (LED), a liquid crystal display element, and a semiconductor laser element using a compound semiconductor; and a light-receiving element such as a photo-coupler.

<<Resin Compositions for Reflecting Light>>

Next, the resin composition for reflecting light of the present invention will be described.

The resin composition for reflecting light of the present invention is a material used for forming a reflecting member as described above, and includes an epoxy resin B having a unit structure X of alicyclic acid anhydride and a unit structure Y of hydrogenated bisphenol, and a colorant. The epoxy resin B preferably further has a unit structure Z of bisphenol-type epoxy.

In addition, the resin composition for reflecting light of the present invention preferably further includes an epoxy resin A having a structure represented by the following formula (1).

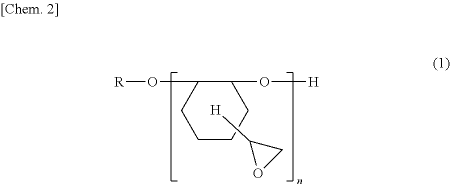

(In the formula (1), R represents a monovalent organic group having 2 to 10 carbon atoms, and n represents an integer of 3 to 50.)

In addition, the resin composition for reflecting light of the present invention preferably further includes an epoxy resin C having an isocyanuric ring.

The resin compositions for reflecting light in the related art had low moldability, and were difficult to be molded into a desired shape. In addition, the resin compositions for reflecting light in the related art had low heat resistance, and had a problem in that yellowing occurs by the heat at the time of molding, the heat at the time of solder joint, and the heat of light emitting elements, and thus reflectance is decreased. In addition, there was also a problem in that peeling off or cracking occur in a light-reflecting member by heat.

In contrast, in the present invention, it is possible to prevent deterioration of characteristics such as reflectance due to yellowing or the like by the heat at the time of molding, the heat of light emitting elements, or the like by including of the epoxy resin B of the above-described structure and the colorant. In addition, it is possible to prevent occurrence of peeling off or cracking in the reflecting member by heat. That is, it is possible to provide the resin composition for reflecting light having excellent heat resistance.

On the other hand, in a case where the resin composition for reflecting light further includes the epoxy resin A, it is possible to improve the moldability of the resin composition for reflecting light.

In addition, in a case where the resin composition for reflecting light further includes the epoxy resin C, it is possible to improve light resistance of the resin composition for reflecting light.

Hereinafter, each component will be described in detail.

[Epoxy Resin A]

The epoxy resin A has a structure represented by the formula (1). By including such an epoxy resin A, it is possible to improve the moldability of the resin composition for reflecting light.

In the formula (1), R represents a monovalent organic group having 2 to 10 carbon atoms, and specifically, preferably represents a group derived from 2,2-bis(hydroxyethyl)-1-butanol.

The weight average molecular weight of such an epoxy resin A is preferably 500 to 5000, and more preferably 1000 to 3000. Thus, it is possible to more effectively improve moldability while maintaining excellent heat resistance.

The content of the epoxy resin A in the resin composition for reflecting light is preferably 1% by mass to 15% by mass, and more preferably 5% by mass to 10% by mass. Thus, it is possible to more effectively improve moldability while suppressing yellowing by heat.

[Epoxy Resin B]

The epoxy resin B has the unit structure X of alicyclic acid anhydride and the unit structure Y of hydrogenated bisphenol. In addition, the epoxy resin B preferably further has the unit structure Z of bisphenol-type epoxy. By including such an epoxy resin B, it is possible to improve the heat resistance of the resin composition for reflecting light.

Examples of the unit structure X of alicyclic acid anhydride include structures of acid anhydrides such as hexahydrophthalic acid, tetrahydrophthalic acid, and the like. Among these, the unit structure X preferably has a unit structure of acid anhydride of hexahydrophthalic acid. Thus, it is possible to further improve moldability while improving heat resistance.

When the content of the unit structure X of alicyclic acid anhydride included in the epoxy resin B is x [% by mass], and the content of the unit structure Y of hydrogenated bisphenol is y [% by mass], it is preferable to satisfy a relationship of 0.5≦y/x. By satisfying such a relationship, it is possible to more reliably prevent yellowing by heat at the time of molding, heat at the time of solder join, heat of light emitting elements, or the like. In addition, it is possible to more effectively prevent occurrence of cracking or peeling off in the reflecting member by heat at the time of molding, heat at the time of solder join, heat of light emitting elements, or the like.

In addition, when the content of the unit structure X of alicyclic acid anhydride included in the epoxy resin B is x [% by mass], and the content of the unit structure Z of bisphenol-type epoxy is z [% by mass], it is preferable to satisfy a relationship of 1.0≦z/x. By satisfying such a relationship, it is possible to more reliably prevent yellowing by heat at the time of molding, heat of light emitting elements, or the like.

The content of the epoxy resin B in the resin composition for reflecting light is preferably 1% by mass to 15% by mass, and more preferably 1% by mass to 10% by mass. Thus, it is possible to more effectively prevent yellowing by heat at the time of molding, heat at the time of solder join, heat of light emitting elements, or the like. In addition, it is possible to more effectively prevent occurrence of cracking or peeling off in the reflecting member by heat at the time of molding, heat at the time of solder join, heat of light emitting elements, or the like.

In addition, when the content of the epoxy resin A is M [% by mass], and the content of the epoxy resin B is N [% by mass], it is preferable to satisfy a relationship of 0.1≦M/N≦10, and it is more preferable to satisfy a relationship of 0.5≦M/N≦6.0. By satisfying such a relationship, it is possible to more effectively improve moldability and heat resistance.

[Epoxy Resin C]

The epoxy resin C is an epoxy resin having an isocyanuric ring. The epoxy resin C is not particularly limited as long as it has two or more epoxy groups and an isocyanuric ring in a molecular. An epoxy resin having a structure in which two or more glycidyl groups are bonded to a nitrogen atom of one isocyanuric ring can be exemplified.

By including such an epoxy resin C, it is possible to improve light resistance of the resin composition for reflecting light.

The weight average molecular weight of such an epoxy resin C is preferably 200 to 3,000, and more preferably 240 to 1,500. Thus, it is possible to more effectively improve light resistance while maintaining excellent heat resistance.

The content of the epoxy resin C in the resin composition for reflecting light is preferably 1% by mass to 15% by mass, and more preferably 5% by mass to 10% by mass. Thus, it is possible to more effectively improve light resistance while suppressing yellowing by heat.

[Curing Agent]

The resin composition for reflecting light of the present invention preferably includes a curing agent.

The curing agent is not particularly limited, and curing agents generally used as a curing agent of an epoxy resin can be used. Examples of such a curing agent include an acid anhydride-based curing agent, an isocyanuric acid derivative-based curing agent, and a phenol-based curing agent. Examples of the acid anhydride-based curing agent include phthalic anhydride, maleic anhydride, trimellitic anhydride, pyromellitic anhydride, hexahydrophthalic anhydride, tetrahydrophthalic anhydride, nadic methyl anhydride, nadic anhydride, glutaric anhydride, dimethyl glutaric anhydride, diethyl glutaric anhydride, succinic anhydride, methylhexahydrophthalic anhydride, and methyltetrahydrophthalic anhydride. Examples of the isocyanuric acid derivative include 1,3,5-tris(1-carboxymethyl)isocyanurate, 1,3,5-tris(2-carboxyethyl)isocyanurate, 1,3,5-tris(3-carboxypropyl)isocyanurate, and 1,3-bis(2-carboxyethyl)isocyanurate. Among these, tetrahydrophthalic anhydride is preferably used, and 1,2,3,6-tetrahydrophthalic anhydride is more preferably used. Thus, it is possible to further improve moldability and heat resistance.

The curing agent is mixed such that active groups (acid anhydride group or hydroxyl group) in the curing agent capable of reacting with the epoxy group becomes preferably 0.5 equivalents to 1.0 equivalent, and more preferably 0.6 equivalents to 0.9 equivalents with respect to one equivalent of epoxy groups in the epoxy resin. Thus, it is possible to more reliably process curing of the resin composition for reflecting light. In addition, it is possible to further enhance heat resistance of the reflecting member.

[Colorant]

The resin composition for reflecting light includes a colorant.

As the colorant, colorants having high reflectivity for light are preferably used, and in particular, a white pigment is more preferably used.

As the white pigment, known white pigments can be used, and the white pigment is not particularly limited. Examples of the white pigment include alumina, magnesium oxide, antimony oxide, titanium oxide, zirconium oxide, and inorganic hollow particles, and among these, one or more types thereof can be used in combination. Among these, in a case where titanium oxide is used, it is possible to further enhance reflectance of light. Moreover, such a white pigment also functions as an inorganic filler described below.

The content of the colorant is preferably less than or equal to 50% by mass, and more preferably 10% by mass to 40% by mass. Thus, it is possible to further improve reflectance of light while maintaining strength of the reflecting member formed.

[Other Components]

The resin composition for reflecting light may include an inorganic filler, a curing accelerator, and a coupling agent in addition to the above-described components.

(Inorganic Filler)

The resin composition for reflecting light may include an inorganic filler.

Examples of the inorganic filler include silica, antimony oxide, aluminum hydroxide, magnesium hydroxide, barium sulfate, magnesium carbonate, barium carbonate, alumina, mica, beryllia, barium titanate, potassium titanate, strontium titanate, calcium titanate, aluminum carbonate, aluminum silicate, calcium carbonate, calcium silicate, magnesium silicate, silicon nitride, boron nitride, clay such as calcined clay, talc, aluminum borate, and silicon carbide. Among these, as the inorganic filler, silica is preferably used. Thus, it is possible to further improve heat resistance of the reflecting member.

The average particle size of the inorganic filler is preferably 5 μm to 30 μm, and more preferably 10 μm to 25 μm.

In addition, the content of the inorganic filler in the resin composition for reflecting light is preferably more than or equal to 30% by mass, and more preferably 40% by mass to 80% by mass. Thus, it is possible to further improve heat resistance while maintaining excellent moldability.

(Curing Accelerator)

The resin composition for reflecting light may include a curing accelerator.

Examples of the curing accelerator include an amine compound, an imidazole compound, an organic phosphorus compound, an alkali metal compound, an alkali earth metal compound, and a quaternary ammonium salt, and one or more types thereof can be used in combination.

Among these curing accelerators, an amine compound, an imidazole compound, and an organic phosphorus compound are preferably used. Examples of the amine compound include 1,8-diaza-bicyclo(5.4.0)undecene-7, triethylenediamine, and tri-2,4,6-dimethylaminomethylphenol. In addition, examples of the imidazole compound include 2-ethyl-4-methylimidazole. Furthermore, examples of the organic phosphorus compound include triphenylphosphine, tetraphenylphosphonium tetraphenylborate, tetra-n-butylphosphonium-o,o-diethylphosphorodithioate, tetra-n-butylphosphonium-tetrafluoroborate, and tetra-n-butylphosphonium-tetraphenylborate.

The content of the curing accelerator in the resin composition for reflecting light is preferably 0.05% by mass to 5.0% by mass, and more preferably 0.1% by mass to 1.0% by mass.

(Coupling Agent)

In addition, the resin composition for reflecting light may include a coupling agent. Thus, it is possible to improve adhesiveness between the epoxy resin and the colorant or the like.

Examples of the coupling agent, which is not particularly limited, include a silane coupling agent and a titanate-based coupling agent.

Examples of the silane coupling agent generally include epoxy silane-based, aminosilane-based, cationic silane-based, vinylsilane-based, acrylic silane-based, and mercaptosilane-based coupling agent, and complex system thereof, and arbitrary added amount thereof can be used.

The content of the coupling agent in the resin composition for reflecting light is preferably less than or equal to 5% by mass.

In addition, in addition to the above-described components, additives such as an antioxidant, a release agent, an ion scavenger, or the like may be added in the resin composition for reflecting light of the present invention.

In addition, the concentration of iron ions in the resin composition for reflecting light of the present invention is preferably less than or equal to 15 ppm, and more preferably less than or equal to 10 ppm. Thus, it is possible to further improve reflectance of light.

Moreover, the concentration of iron ions can be measured by an atomic absorption spectrophotometry.

Such a resin composition for reflecting light can be obtained by dispersively homogeneously mixing the above-described various components.

As a general method of preparing the resin composition for reflecting light, a method in which after the above-described various components are kneaded by an extruding machine, a kneader, a roll, an extruder, or the like, the kneaded material is cooled, and pulverized can be exemplified.

The resin composition for reflecting light obtained in this manner is molded by a method such as an injection molding, a transfer molding, and a compression molding, whereby a reflecting member can be obtained.

<<Second Embodiment of Optical Semiconductor Device>>

Next, a second embodiment of the optical semiconductor device will be described.

FIG. 3 is a longitudinal cross-sectional view showing the second embodiment of the optical semiconductor device.

Next, the second embodiment will be described while focusing on the difference from the embodiment described above, and the description of the same contents will not be repeated. Moreover, the same reference numerals are given to the same configurations as those in the embodiment described above.

As shown in FIG. 3, an optical semiconductor device 100′ according to the embodiment has the mounting portion 1 over which the optical semiconductor element 5 is mounted, the wire pattern 2 which is disposed adjacent to the mounting portion 1, the reflecting member 3 which is disposed around the mounting portion 1, and the optical semiconductor element 5.

In addition, in the same manner as the embodiment described above, the optical semiconductor element 5 is mounted over the mounting portion 1 by the die attach material 6.

In addition, the optical semiconductor element 5 is electrically connected to the wire pattern 2 by the bonding wire 7.

In addition, the optical semiconductor element 5 and the bonding wire 7 are encapsulated with the transparent encapsulating material 8 as shown in FIG. 3.

Examples of the optical semiconductor element 5 include light emitting elements such as a Light Emitting Diode (LED), a liquid crystal display element, and a semiconductor laser element using a compound semiconductor; and a light-receiving element such as a photo-coupler.

The optical semiconductor device 100′ of the embodiment is different from the embodiment described above in terms of using the reflecting member 3 not having an inclined surface.

Hereinbefore, the resin composition for reflecting light of the present invention, the substrate for mounting optical semiconductor element, and the optical semiconductor device have been described, but the present invention is not limited thereto. For example, arbitrary constituents may also be added to the substrate for mounting optical semiconductor element or the optical semiconductor device.

### EXAMPLES

Next, specific examples of the present invention will be described.

### [1] Manufacture of Resin Composition for Reflecting Light

### Examples 1 to 13

Respective components shown in Table 1 were homogeneously mixed at 10° C. to 50° C. using a mixer.

Thereafter, the mixture was melt and kneaded using a kneader, cooled, and pulverized, whereby a resin composition for reflecting light was obtained.

### Comparative Examples 1 and 2

A resin composition for reflecting light was obtained by the same method as in the above-described Examples, without adding the epoxy resin B.

### Comparative Example 3

A resin composition for reflecting light was obtained by the same method as in the above-described Examples, without adding the epoxy resin A and the epoxy resin B.

In addition, as the inorganic filler, SO-32R was silica having an average particle size (d₅₀) of 1.5 μm, ES-508 was a silica having an average particle size (d₅₀) of 26 μm and a particle cut greater than or equal to 75 μm, and FB-7SDC was a silica having an average particle size (d₅₀) of 5.8 μm and a particle cut greater than or equal to 30 μm.

In addition, EHPE-3150 (manufactured by Daicel Chemical Industries, Ltd.) was a 1,2-epoxy-4-(2-oxiranyl)cyclohexane adduct of 2,2-bis(hydroxymethyl)-1-butanol.

In addition, ST-6100 (manufactured by Nippon Steel & Sumikin Chemical Co., Ltd., softening point: 100° C.) was a polymerization reaction product of acid anhydride of hexahydrophthalic acid, 2,2′-bis(4-hydroxycyclohexyl)propane, and a bisphenol A-type epoxy.

In addition, TEPIC-SP (manufactured by Nissan Chemical Industries, Ltd.) was triglycidylisocyanurate. In addition, MA-DGIC (manufactured by Shikoku Chemicals Corporation) was monoallyl diglycidyl isocyanurate.

In addition, the concentration of iron ions in respective Examples and Comparative examples was measured by an atomic absorption spectrophotometry, and the concentration was less than or equal to 15 ppm.

Moreover, compositions in respective Examples and Comparative examples are shown in Table 1.

TABLE 1

| Raw material | Material | | | | | | | |
|---|---|---|---|---|---|---|---|---|
| type | name | Manufacturer | Example 1 | Example 2 | Example 3 | Example 4 | Example 5 | Example 6 |
| Silica [% by | SO-32R | Admatechs | 10.0 | 10.0 | 10.0 | 10.0 | 10.0 | 10.0 |
| mass] | ES-508 | Tokai-minerals | 53.0 | 53.0 | 53.0 | 54.0 | 55.0 | 56.5 |
| | | Co., Ltd. | | | | | | |
| | FB-7SDC | Denki Kagaku | | | | | | |
| | | Kogyo | | | | | | |
| | | Kabushiki | | | | | | |
| | | Kaisha | | | | | | |
| Epoxy resin | EHPE-3150 | Daicel | 5.6 | 5.6 | 5.6 | 6.8 | 6.3 | 6.5 |
| A M [% by | | Chemical | | | | | | |
| mass] | | Industries, | | | | | | |
| | | Ltd. | | | | | | |
| Epoxy resin | ST-6100 | Nippon Steel & | 5.6 | 5.6 | 5.6 | 2.9 | 2.7 | 1.2 |
| B N [% by | | Sumikin | | | | | | |
| mass] | | Chemical Co., | | | | | | |
| | | Ltd. | | | | | | |
| Epoxy resin | TEPIC-SP | Nissan | | | | | | |
| C1 [% by | | chemical | | | | | | |
| mass] | | Industries, | | | | | | |
| | | Ltd. | | | | | | |
| Epoxy resin | MA-DGIC | Shikoku | | | | | | |
| C2 [% by | | Chemicals | | | | | | |
| mass] | | Corporation | | | | | | |
| Curing | RIKACID | New Japan | 4.1 | 4.1 | 4.4 | 4.6 | 4.4 | 4.3 |
| agent [% by | TH | Chemical Co., | | | | | | |
| mass] | | Ltd. | | | | | | |
| | RIKACID | New Japan | | | | | | |
| | HH | Chemical Co., | | | | | | |
| | | Ltd. | | | | | | |
| Curing | C03-MB | Sumitomo | 0.5 | 0.5 | | 0.5 | 0.4 | 0.3 |
| accelerator | | Bakelite Co., | | | | | | |
| [% by mass] | | Ltd. | | | | | | |
| | PX-4MP | Nippon | | | 0.2 | | | |
| | | chemical | | | | | | |
| | | Industrial | | | | | | |
| | | Co., Ltd. | | | | | | |
| Wax [% by | Licowax | Clariant Japan K. K. | | | | | | |
| mass] | PED 191 | | | | | | | |
| | NAA-160 | NOF | 0.2 | 0.2 | 0.2 | 0.2 | 0.2 | 0.2 |
| | | CORPORATION | | | | | | |
| Antioxidant | AO-60 | ADEKA | 0.5 | 0.5 | 0.5 | 0.5 | 0.5 | 0.5 |
| [% by mass] | 2112 | ADEKA | 0.5 | 0.5 | 0.5 | 0.5 | 0.5 | 0.5 |
| White | PF-690 | Ishihara | 20.0 | | | | | |
| pigment | | sangyo kaisha, | | | | | | |
| (titanium | | Ltd. | | | | | | |
| oxide) [% by | PF-726 | Ishihara | | 20.0 | 20.0 | 20.0 | 20.0 | 20.0 |
| mass] | | sangyo kaisha, | | | | | | |
| | | Ltd. | | | | | | |
| TOTAL [% by mass] | | | 100.0 | 100.0 | 100.0 | 100.0 | 100.0 | 100.0 |
| Content of inorganic filler [% by mass] | | | 83.0 | 83.0 | 83.0 | 84.0 | 85.0 | 86.5 |
| M/N | | | 1.0 | 1.0 | 1.0 | 2.3 | 2.3 | 5.4 |
| Raw material | Material | | | | | Example | Example | Example |
| type | name | Manufacturer | Example 7 | Example 8 | Example 9 | 10 | 11 | 12 |
| Silica [% by | SO-32R | Admatechs | 10.0 | 10.0 | 10.0 | 10.0 | 10.0 | 10.0 |
| mass] | ES-508 | Tokai-minerals | 56.5 | 56.5 | 57.5 | 58.0 | 57.5 | 57.5 |
| | | Co., Ltd. | | | | | | |
| | FB-7SDC | Denki Kagaku | | | | | | |
| | | Kogyo | | | | | | |
| | | Kabushiki | | | | | | |
| | | Kaisha | | | | | | |
| Epoxy resin | EHPE-3150 | Daicel | 6.2 | 5.9 | 6.0 | 5.7 | | |
| A M [% by | | Chemical | | | | | | |
| mass] | | Industries, | | | | | | |
| | | Ltd. | | | | | | |
| Epoxy resin | ST-6100 | Nippon Steel & | 1.6 | 2.0 | 1.1 | 1.0 | 1.2 | 1.1 |
| B N [% by | | Sumikin | | | | | | |
| mass] | | Chemical Co., | | | | | | |
| | | Ltd. | | | | | | |
| Epoxy resin | TEPIC-SP | Nissan | | | | | 6.6 | 6.0 |
| C1 [% by | | chemical | | | | | | |
| mass] | | Industries, | | | | | | |
| | | Ltd. | | | | | | |
| Epoxy resin | MA-DGIC | Shikoku | | | | | | |
| C2 [% by | | Chemicals | | | | | | |
| mass] | | Corporation | | | | | | |
| Curing | RIKACID | New Japan | 4.2 | 4.1 | 3.9 | 3.8 | 3.3 | 4.0 |
| agent [% by | TH | Chemical Co., | | | | | | |
| mass] | | Ltd. | | | | | | |
| | RIKACID | New Japan | | | | | | |
| | HH | Chemical Co., | | | | | | |
| | | Ltd. | | | | | | |
| Curing | C03-MB | Sumitomo | 0.3 | 0.3 | 0.3 | 0.3 | 0.2 | 0.2 |
| accelerator | | Bakelite Co., | | | | | | |
| [% by mass] | | Ltd. | | | | | | |
| | PX-4MP | Nippon | | | | | | |
| | | chemical | | | | | | |
| | | Industrial | | | | | | |
| | | Co., Ltd. | | | | | | |
| Wax [% by | Licowax | Clariant Japan K. K. | | | | | | |
| mass] | PED 191 | | | | | | | |
| | NAA-160 | NOF | 0.2 | 0.2 | 0.2 | 0.2 | 0.2 | 0.2 |
| | | CORPORATION | | | | | | |
| Antioxidant | AO-60 | ADEKA | 0.5 | 0.5 | 0.5 | 0.5 | 0.5 | 0.5 |
| [% by mass] | 2112 | ADEKA | 0.5 | 0.5 | 0.5 | 0.5 | 0.5 | 0.5 |
| White | PF-690 | Ishihara | | | | | | |
| pigment | | sangyo kaisha, | | | | | | |
| (titanium | | Ltd. | | | | | | |
| oxide) [% by | PF-726 | Ishihara | 20.0 | 20.0 | 20.0 | 20.0 | 20.0 | 20.0 |
| mass] | | sangyo kaisha, | | | | | | |
| | | Ltd. | | | | | | |

| | | | | | | |
|---|---|---|---|---|---|---|
| TOTAL [% by mass] | 100.0 | 100.0 | 100.0 | 100.0 | 100.0 | 100.0 |
| Content of inorganic filler [% by mass] | 86.5 | 86.5 | 87.5 | 88.0 | 87.5 | 87.5 |
| M/N | 3.9 | 3.0 | 5.5 | 5.7 | — | — |

| Raw material | Material | | | Comparative | Comparative | Comparative |
|---|---|---|---|---|---|---|
| type | name | Manufacturer | Example 13 | example 1 | example 2 | example 3 |
| Silica [% by | SO-32R | Admatechs | 10.0 | 10.0 | 10.0 | 10.0 |
| mass] | ES-508 | Tokai-minerals | 57.5 | 53.0 | 57.5 | |
| | | Co., Ltd. | | | | |
| | FB-7SDC | Denki Kagaku | | | | 52.0 |
| | | Kogyo | | | | |
| | | Kabushiki | | | | |
| | | Kaisha | | | | |
| Epoxy resin | EHPE-3150 | Daicel | | 11.2 | 6.7 | |
| A M [% by | | Chemical | | | | |
| mass] | | Industries, | | | | |
| | | Ltd. | | | | |
| Epoxy resin | ST-6100 | Nippon Steel & | 1.1 | | | |
| B N [% by | | Sumikin | | | | |
| mass] | | Chemical Co., | | | | |
| | | Ltd. | | | | |
| Epoxy resin | TEPIC-SP | Nissan | | | | 8.4 |
| C1 [% by | | chemical | | | | |
| mass] | | Industries, | | | | |
| | | Ltd. | | | | |
| Epoxy resin | MA-DGIC | Shikoku | 6.1 | | | |
| C2 [% by | | Chemicals | | | | |
| mass] | | Corporation | | | | |
| Curing | RIKACID | New Japan | 3.9 | 4.1 | 4.3 | 4.6 |
| agent [% by | TH | Chemical Co., | | | | |
| mass] | | Ltd. | | | | |
| | RIKACID | New Japan | | | | 4.6 |
| | HH | Chemical Co., | | | | |
| | | Ltd. | | | | |
| Curing | C03-MB | Sumitomo | 0.2 | 0.5 | 0.3 | |
| accelerator | | Bakelite Co., | | | | |
| [% by mass] | | Ltd. | | | | |
| | PX-4MP | Nippon | | | | 0.2 |
| | | chemical | | | | |
| | | Industrial | | | | |
| | | Co., Ltd. | | | | |
| Wax [% by | Licowax | Clariant Japan K. K. | | | | |
| mass] | PED 191 | | | | | |
| | NAA-160 | NOF | 0.2 | 0.2 | 0.2 | 0.2 |
| | | CORPORATION | | | | |
| Antioxidant | AO-60 | ADEKA | 0.5 | 0.5 | 0.5 | |
| [% by mass] | 2112 | ADEKA | 0.5 | 0.5 | 0.5 | |
| White | PF-690 | Ishihara | | 20.0 | | |
| pigment | | sangyo kaisha, | | | | |
| (titanium | | Ltd. | | | | |
| oxide) [% by | PF-726 | Ishihara | 20.0 | | 20.0 | 20.0 |
| mass] | | sangyo kaisha, | | | | |
| | | Ltd. | | | | |

| | | | | |
|---|---|---|---|---|
| TOTAL [% by mass] | 100.0 | 100.0 | 100.0 | 100.0 |
| Content of inorganic filler [% by mass] | 83.0 | 87.5 | 87.5 | 83.0 |
| M/N | — | — | — | — |

### [2] Manufacture of Reflecting Member (Substrate for Mounting Optical Semiconductor Element)

The obtained resin composition for reflecting light was applied to a silver-plated copper frame under the conditions of a molding temperature of 175° C., an injection pressure of 12 MPa, and a curing time of 120 seconds to form a reflecting member.

### [3] Evaluation

[3-1] Evaluation of reflectance of light (degree of whiteness)

The obtained resin composition for reflecting light was molded under the conditions of a die temperature of 175° C., an injection pressure of 9.8 MPa, and a curing time of 120 seconds using a low pressure transfer molding press (TEP-50-30, manufactured by Towaseiki Co., Ltd.) to produce a test disk having a diameter of 50 mmΦ and a thickness of 2.5 mm. The initial degree of whiteness of the surface of the test disk and the degree of whiteness of that after treatment at 200° C. for 48 hours were measured using a colorimeter (color leader, CR13, manufactured by Konica Minolta, Inc.).

Quality determination of the degree of whiteness was performed as follows.

A: The degree of whiteness is greater than or equal to 90%.

B: The degree of whiteness is greater than or equal to 80% and less than 90%.

C: The degree of whiteness is greater than or equal to 70% and less than 80%.

D: The degree of whiteness is less than 70%.

[3-2] Evaluation of Fluidity

Spiral flow: The resin composition for reflecting light was injected into a mold for measuring spiral flow according to EMMI-1-66 under the conditions of 175° C., an injection pressure of 6.9 MPa, and a pressure hold time of 120 seconds using a low pressure transfer molding press (KTS-15, manufactured by Kohtaki Precision Machine Co., Ltd.), and a flow length (cm) was measured.

[3-3] Evaluation of Moldability

The obtained resin composition for reflecting light was molded under the conditions of a die temperature of 175° C., an injection pressure of 9.8 MPa, and a curing time of 120 seconds using a transfer molding press (TEP-50-30, manufactured by Towaseiki Co., Ltd.) to produce a test disk having a diameter of 50 mmΦ and a thickness of 2.5 mm. The ease of release and the state of appearance at the time of removing the test disk from the molding die were evaluated as follows.

A: Since both filling properties and release properties are excellent, there was no problem.

B: Release was possible by air blow.

C: Release was difficult even by air blow.

D: Unfilling of the resin composition for reflecting light was observed. Molding defective.

[3-4] Evaluation of Moisture Resistance Reflow Properties

The substrate for mounting optical semiconductor element manufactured according to the method of the above-mentioned [2] was heat-treated at 150° C. for 4 hours as a post-curing, and humidification-treated at 30° C., and a relative humidity of 60% for 168 hours. Thereafter, an IR reflow treatment (260° C., JEDEC LEVEL3) was performed, and an adhesion state of the interface between the resin composition for reflecting light (molded product) and the substrate for mounting optical semiconductor element, and the presence of cracks were observed by ultrasonic flaw detector (manufactured by Hitachi Kenki FineTech Co., Ltd.). A peeling off occurrence rate [the number of peeling off occurrence elements/the total number of optical semiconductor elements×100(%)] was calculated, and evaluated according to the following evaluation criteria.

B: Peeling off did not occur

C: The peeling off occurrence rate was less than 20%.

D: The peeling off occurrence rate was greater than or equal to 20%.

The evaluation results are shown in Table 2.

TABLE 2

| Evaluation | | Example 1 | Example 2 | Example 3 | Example 4 | Example 5 | Example 6 | Example 7 | Example 8 | Example 9 |
|---|---|---|---|---|---|---|---|---|---|---|
| Reflectance | Initial | A | A | A | A | A | A | A | A | A |
| of | After | B | B | B | B | B | B | B | B | B |
| light | storing | | | | | | | | | |
| | at high | | | | | | | | | |
| | temperature | | | | | | | | | |
| | of | | | | | | | | | |
| | 200° C. for | | | | | | | | | |
| | 48 hours | | | | | | | | | |

| | | | | | | | | | |
|---|---|---|---|---|---|---|---|---|---|
| Fluidity | 100 | 110 | 120 | 120 | 75 | 70 | 90 | 65 | 60 |
| Moldability | B | B | B | B | B | B | B | B | A |
| Moisture resistance | C | C | C | B | B | B | B | B | B |
| reflow | | | | | | | | | |
| Total determination | B | B | B | B | B | B | B | B | B |

| | | Example | Example | Example | Example | Comparative | Comparative | Comparative |
|---|---|---|---|---|---|---|---|---|
| Evaluation | | 10 | 11 | 12 | 13 | example 1 | example 2 | example 3 |
| Reflectance | Initial | A | A | A | A | A | A | Molding |
| of | After | B | B | B | B | D | D | is |
| light | storing | | | | | | | impossible |
| | at high | | | | | | | |
| | temperature | | | | | | | |
| | of | | | | | | | |
| | 200° C. for | | | | | | | |
| | 48 hours | | | | | | | |

| | | | | | | | |
|---|---|---|---|---|---|---|---|
| Fluidity | 40 | 90 | 60 | 100 | 100 | 60 | |
| Moldability | A | B | A | B | C | A | |
| Moisture resistance | B | C | C | C | D | C | — |
| reflow | | | | | | | |
| Total determination | B | B | B | B | D | D | D |

As clearly seen from Table 2, the resin composition for reflecting light of the present invention had excellent moldability. In addition, in the substrate for mounting optical semiconductor element using the resin composition for reflecting light of the present invention, heat resistance was excellent, and decrease in reflectance of light was suppressed. In contrast, in Comparative examples, satisfactory result was not obtained.

This application claims a priority based on Japanese Patent Application No. 2012-072566, filed on Mar. 27, 2012, Japanese Patent Application No. 2012-112746, filed on May 16, 2012, and Japanese Patent Application No. 2012-148620, filed on Jul. 2, 2012, the contents of which are incorporated herein by reference.

1. A resin composition for reflecting light, comprising:
an epoxy resin B having a unit structure X of alicyclic acid anhydride and a unit structure Y of hydrogenated bisphenol; and
a colorant.

2. The resin composition for reflecting light according to claim 1,
wherein the epoxy resin B further has a unit structure Z of bisphenol-type epoxy.

3. The resin composition for reflecting light according to claim 1, further comprising:
an epoxy resin A having a structure represented by a following formula 1. 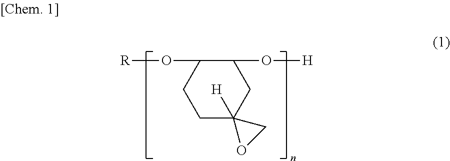
(In the formula (1), R represents a monovalent organic group having 2 to 10 carbon atoms, and n represents an integer of 3 to 50.)

4. The resin composition for reflecting light according to claim 3 satisfying a relationship of 0.1≦M/N≦10 when a content of the epoxy resin A is M [% by mass] and a content of the epoxy resin B is N [% by mass].

5. The resin composition for reflecting light according to claim 3,
wherein the content of the epoxy resin A is 1% by mass to 15% by mass.

6. The resin composition for reflecting light according to claim 1,
wherein the content of the epoxy resin B is 1% by mass to 15% by mass.

7. The resin composition for reflecting light according to claim 1, further comprising:
an epoxy resin C having an isocyanuric ring.

8. The resin composition for reflecting light according to claim 7,
wherein a content of the epoxy resin C is 1% by mass to 15% by mass.

9. The resin composition for reflecting light according to claim 1, further comprising:
a curing agent.

10. The resin composition for reflecting light according to claim 1,
wherein a concentration of iron ions is less than or equal to 15 ppm.

11. The resin composition for reflecting light according to claim 1, comprising:
an inorganic filler,
wherein a content of the inorganic filler is greater than or equal to 30% by mass.

12. The resin composition for reflecting light according to claim 1,
wherein the colorant is titanium oxide.

13. The resin composition for reflecting light according to claim 1,
wherein a content of the colorant is less than or equal to 50% by mass.

14. A substrate for mounting optical semiconductor element, comprising:
a reflecting member constituted with the resin composition for reflecting light according to claim 1.

15. An optical semiconductor device comprising:
a reflecting member constituted with the resin composition for reflecting light according to claim 1; and
a light emitting element.
